(19) United States
(12) Patent Application Publication
(10) Pub. No.: US 2023/0411233 A1
(43) Pub. Date: Dec. 21, 2023

(54) SEMICONDUCTOR DEVICE AND METHOD OF MANUFACTURING THE SAME

(71) Applicant: RENESAS ELECTRONICS CORPORATION, Tokyo (JP)

(72) Inventor: Tatsuya USAMI, Tokyo (JP)

(21) Appl. No.: 18/304,880

(22) Filed: Apr. 21, 2023

(30) Foreign Application Priority Data
Jun. 20, 2022 (JP) 2022-099043

(51) Int. Cl. H01L 23/31; H01L 23/00; H01L 21/56

(52) U.S. Cl. CPC H01L 23/3192; H01L 23/291; H01L 24/05; H01L 24/03; H01L 24/06; H01L 21/56; H01L 2224/03614; H01L 2224/05082; H01L 2224/05166; H01L 2224/05186; H01L 2924/04941; H01L 2224/05573; H01L 2224/05624; H01L 2224/05561; H01L 2224/05567; H01L 2224/06155; H01L 2224/45144; H01L 2224/45147; H01L 24/45

(57) ABSTRACT

Wirings next to each other spaced apart by a first distance are formed in the uppermost layer of a multilayer wiring layer formed on a semiconductor substrate. A protective film covers upper surfaces and side surfaces of the wirings. The protective films formed on the side surfaces of the wirings are spaced apart from each other. The protective film is formed of an inorganic dielectric film. A thickness of the protective film formed on the upper surfaces of the wirings is larger than a thickness of the protective film formed on the side surfaces of the wirings.

### CROSS-REFERENCE TO RELATED APPLICATIONS

The disclosure of Japanese Patent Application No. 2022-099043 filed on Jun. 20, 2022, including the specification, drawings and abstract is incorporated herein by reference in its entirety.

### BACKGROUND

The present disclosure relates to a semiconductor device and a method of manufacturing the same and, for example, to the semiconductor device including a protective film covering an uppermost layer wiring and the method of manufacturing the same.

In a typical semiconductor device (semiconductor chip), a multilayer wiring layer is formed on a semiconductor substrate, and an uppermost layer wiring of the multilayer wiring layer is mainly formed of, for example, an aluminum film. The uppermost layer wiring is covered with a protective film, and by providing an opening in a part of the protective film, a part of the uppermost layer wiring exposed from the opening serves as a pad electrode. By connecting an external connection member such as wire bonding to the pad electrode, the semiconductor device is electrically connected to another semiconductor device or wiring substrate.

In recent years, compatibility of miniaturization and cost reduction of semiconductor device has been demanded. Although the uppermost layer wiring is covered with the protective film, in order to satisfy the above-mentioned demand, an inorganic dielectric film such as a silicon oxide film and a silicon nitride film is applied as such a protective film. In addition, it is demanded to apply a structure (non-filled structure) in which a space between uppermost layer wirings next to each other is not completely filled with the inorganic dielectric film.

There are disclosed techniques listed below.
[Patent Document 1] Japanese Unexamined Patent Application Publication No. 2017-183672

For example, Patent Document 1 discloses a semiconductor device including a multilayer wiring layer formed on a semiconductor substrate and a protective film covering uppermost layer wirings of the multilayer wiring layer. In Patent Document 1, a space between the uppermost layer wirings is filled with the protective film.

### SUMMARY

According to studies conducted by the inventors of the present application, it is found out that, when the inorganic dielectric film is applied as the protective film for the non-filled structure as described above, a crack tends to occur in the protective film on an upper surface side and a side surface side of the uppermost layer wiring. Therefore, the reliability of the semiconductor device is deteriorated.

Other objects and novel features will become apparent from the description of this specification and the accompanying drawings.

The typical ones of the embodiments disclosed in the present application will be briefly described as follows.

A semiconductor device according to one embodiment includes a multilayer wiring layer formed on a semiconductor substrate, a first wiring and a second wiring formed in an uppermost layer of the multilayer wiring layer and being next to each other spaced apart by a first distance, and a protective film formed so as to cover an upper surface and a side surface of each of the first wiring and the second wiring. Here, the protective film formed on the side surface of the first wiring and the protective formed on the side surface of the second wiring are spaced apart from each other, the protective film is formed of an inorganic dielectric film, and a thickness of the protective film formed on the upper surface of the first wiring or on the upper surface of the second wiring is larger than a thickness of the protective film formed on the side surface of the first wiring or on the side surface of the second wiring.

A method of manufacturing a semiconductor device according to one embodiment includes: (a) forming wiring layers on a semiconductor substrate; (b) forming a first conductive film on the wiring layers; (c) forming a first inorganic film on the first conductive film; (d) patterning the first inorganic dielectric film and the first conductive film to form a first wiring and a second wiring next to each other spaced apart by a first distance such that the first inorganic dielectric film is left on an upper surface of each of the first wiring and the second wiring; (e) forming a second inorganic dielectric film on the upper surface of each of the first wiring and the second wiring via the first inorganic dielectric film, and forming the second inorganic dielectric film on a side surface of each of the first wiring and the second wiring; and (f) forming a third inorganic dielectric film on the upper surface of each of the first wiring and the second wiring via the first inorganic dielectric film and the second inorganic dielectric film, and forming the third inorganic dielectric film on the side surface of each of the first wiring and the second wiring via the second inorganic dielectric film. Here, the wiring layers, the first wiring and the second wiring configure a multilayer wiring layer where the first wiring and the second wiring are uppermost layer wirings, the third inorganic dielectric film formed on the side surface of the first wiring and the third inorganic dielectric film formed on the side surface of the second wiring are spaced apart from each other, and a sum of thicknesses of the first inorganic dielectric film, the second inorganic dielectric film and the third inorganic dielectric film formed on the upper surface of the first wiring or on the upper surface of the second wiring is larger than a sum of thicknesses of the second inorganic dielectric film and the third inorganic dielectric film formed on the side surface of the first wiring or on the side surface of the second wiring.

A method of manufacturing a semiconductor device according to one embodiment includes: (a) forming a multilayer wiring layer including a first wiring and a second wiring next to each other spaced apart by a first distance on a semiconductor substrate, the first wiring and the second wiring being uppermost layer wirings; (b) forming a fourth inorganic dielectric film on an upper surface of each of the first wiring and the second wiring, and forming the fourth inorganic dielectric film on a side surface of each of the first wiring and the second wiring; (c) forming a fifth inorganic dielectric film on the upper surface of each of the first wiring and the second wiring via the fourth inorganic dielectric film, and forming the fifth inorganic dielectric film on the side surface of each of the first wiring and the second wiring via the fourth inorganic dielectric film; and (d) forming a sixth inorganic dielectric film on the upper surface of each of the first wiring and the second wiring via the fourth inorganic dielectric film and the fifth inorganic dielectric film, and forming the sixth inorganic dielectric film on the side surface of each of the first wiring and the second wiring via the fourth inorganic dielectric film and the fifth inorganic dielectric film. Here, a thickness of the fifth inorganic dielectric film formed on the upper surface of the first wiring or on the upper surface of the second wiring is more than twice a thickness of the fifth inorganic dielectric film formed on the side surface of the first wiring or on the side surface of the second wiring, the sixth inorganic dielectric film formed on the side surface of the first wiring and the sixth inorganic dielectric film formed on the side surface of the second wiring are spaced apart from each other, and a sum of thicknesses of the fourth inorganic dielectric film, the fifth inorganic dielectric film and the sixth inorganic dielectric film formed on the upper surface of the first wiring or on the upper surface of the second wiring is larger than a sum of thicknesses of the fourth inorganic dielectric film, the fifth inorganic dielectric film and the sixth inorganic dielectric film formed on the side surface of the first wiring or on the side surface of the second wiring.

According to one embodiment, the reliability of the semiconductor device can be improved.

### BRIEF DESCRIPTION OF THE DRAWINGS

FIG. 1 is a plan view showing an entire semiconductor device in a first embodiment.

FIG. 2A is a cross-sectional view showing the semiconductor device in the first embodiment.

FIG. 2B is a cross-sectional view showing the semiconductor device in the first embodiment.

FIG. 3 is a cross-sectional view showing the semiconductor device in the first embodiment.

FIG. 4 is a table showing the results of experiments conducted by the present inventor.

FIG. 5 is a graph showing the results of experiments conducted by the present inventor.

FIG. 6 is a graph showing the results of experiments conducted by the present inventor.

FIG. 7 is a cross-sectional view showing a manufacturing step of the semiconductor device in the first embodiment.

FIG. 8A is a cross-sectional view showing the manufacturing step of the semiconductor device following FIG. 7.

FIG. 8B is a cross-sectional view showing the manufacturing step of the semiconductor device following FIG. 7.

FIG. 9A is a cross-sectional view showing the manufacturing step of the semiconductor device following FIG. 8A.

FIG. 9B is a cross-sectional view showing the manufacturing step of the semiconductor device following FIG. 8B.

FIG. 10A is a cross-sectional view showing the manufacturing step of the semiconductor device following FIG. 9A.

FIG. 10B is a cross-sectional view showing the manufacturing step of the semiconductor device following FIG. 9B.

FIG. 11A is a cross-sectional view showing the manufacturing step of the semiconductor device following FIG. 10A.

FIG. 11B is a cross-sectional view showing the manufacturing step of the semiconductor device following FIG. 10B.

FIG. 12A is a cross-sectional view showing a semiconductor device in a second embodiment.

FIG. 12B is a cross-sectional view showing the semiconductor device in the second embodiment.

FIG. 13A is a cross-sectional view showing a manufacturing step of the semiconductor device in the second embodiment.

FIG. 13B is a cross-sectional view showing the manufacturing step of the semiconductor device in the second embodiment.

FIG. 14A is a cross-sectional view showing the manufacturing step of the semiconductor device following FIG. 13A.

FIG. 14B is a cross-sectional view showing the manufacturing step of the semiconductor device following FIG. 13B.

FIG. 15A is a cross-sectional view showing the manufacturing step of the semiconductor device following FIG. 14A.

FIG. 15B is a cross-sectional view showing the manufacturing step of the semiconductor device following FIG. 14B.

FIG. 16A is a cross-sectional view showing the manufacturing step of the semiconductor device following FIG. 15A.

FIG. 16B is a cross-sectional view showing the manufacturing step of the semiconductor device following FIG. 15B.

FIG. 17 is a cross-sectional view showing a semiconductor device in an examined example.

### DETAILED DESCRIPTION

Hereinafter, embodiments will be described in detail based on the drawings. In all the drawings for explaining the embodiments, members having the same functions are denoted by the same reference numerals, and repetitive descriptions thereof are omitted. In the following embodiments, descriptions of the same or similar parts will not be repeated in principle except when particularly necessary.

In addition, the X direction, the Y direction, and the Z direction described in the present application intersect each other and are orthogonal to each other. In the present application, the Z direction is described as a vertical direction, a height direction, or a thickness direction of a certain structure. In addition, the expression “plan view” used in the present application means that the plane formed by the X direction and the Y direction is a “plane” and the “plane” is viewed from the Z direction.

### First Embodiment

### Structure of Semiconductor Device

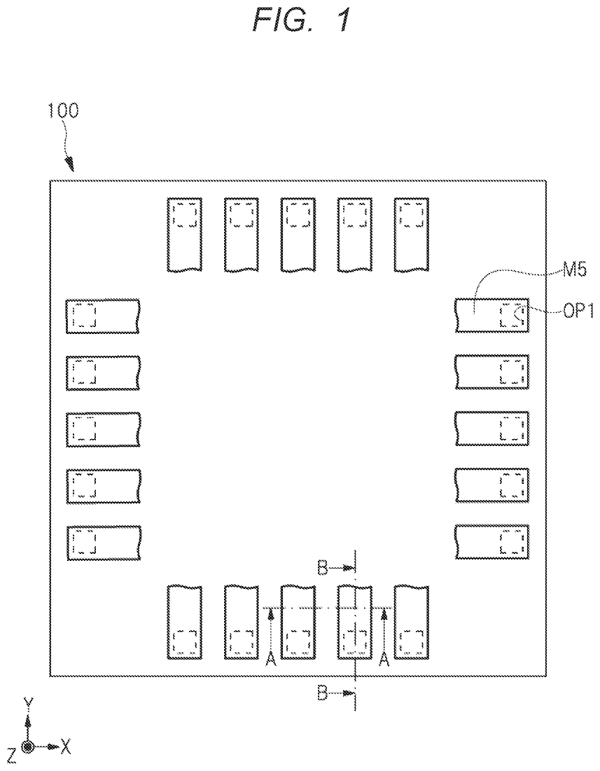

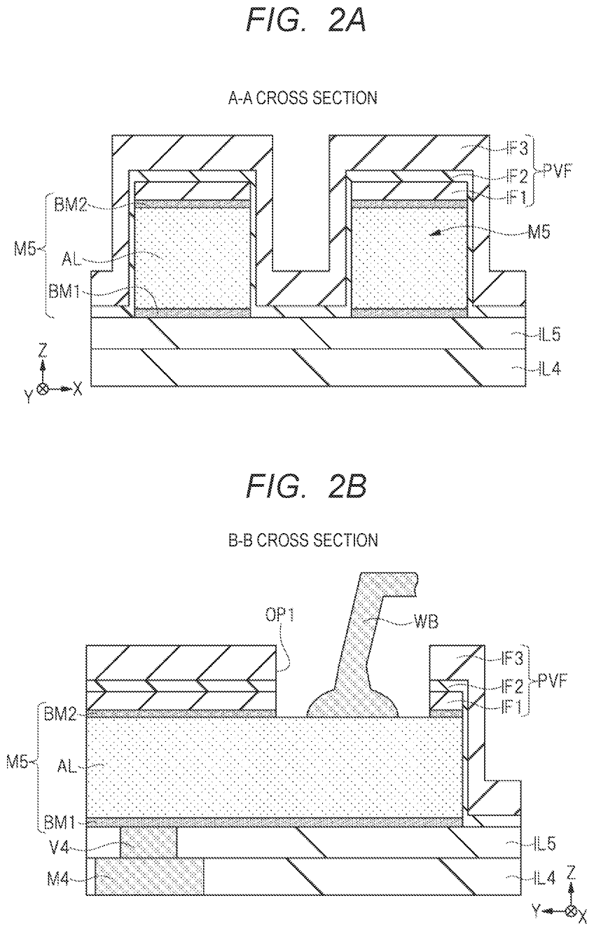

A semiconductor device 100 in the first embodiment will be described below with reference to FIGS. 1, 2A, and 2B. FIG. 1 is a plan view showing the semiconductor device 100. FIG. 2A is a cross-sectional view along A-A line shown in FIG. 1, and FIG. 2B is a cross-sectional view along B-B line shown in FIG. 1.

The semiconductor device 100 includes a semiconductor substrate on which semiconductor elements are formed, and a multilayer wiring layer formed on the semiconductor substrate. Examples of the semiconductive elements include a MISFET (Metal Oxide Semiconductor Field Effect Transistor), a resistor element, and a capacitor element.

As shown in FIG. 1, wirings M5 are formed in an uppermost layer of the multilayer wiring layer. As shown in 2B, the wirings M5 are covered with a protective film PVF, and opening portions OP1 are provided in the protective film PVF so as to reach parts of upper surfaces of the wirings M5. Parts of the wirings M5 exposed in the opening portions OP1 serve as pad electrodes.

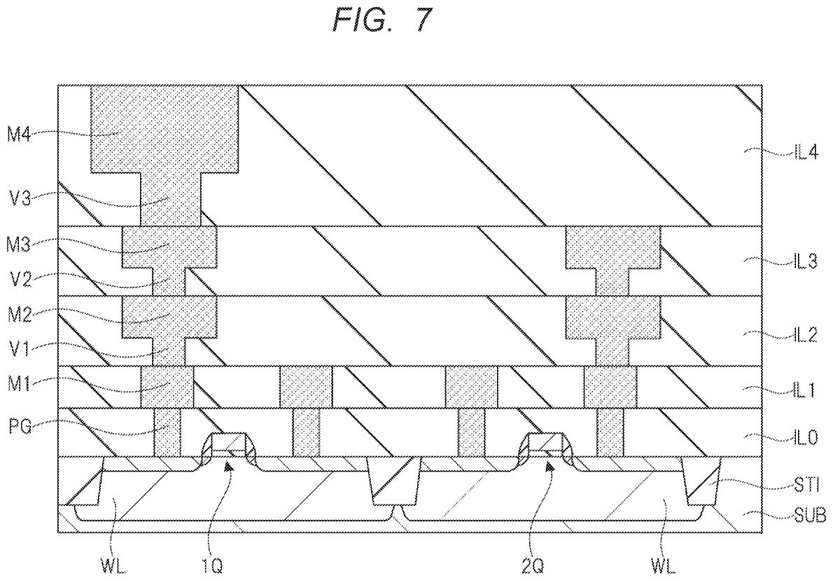

Note that the main feature of the first embodiment is a structure around the wirings M5, which is the uppermost layer wirings, and therefore, in the FIGS. 2A and 2B, wirings M4 and an upper layer structure thereof are shown, and a lower layer structure of the wirings M4 is not shown. A detailed description of the lower layer structure and manufacturing method thereof will be described with reference to FIG. 7 in MANUFACTURING METHOD OF SEMICONDUCTOR DEVICE described later.

Further, although the case where the multilayer wiring layer is formed of five wiring layers and the uppermost layer wirings are the wirings M5 is explained, the number of wiring layers may be less than five or more than five.

As shown in FIGS. 2A and 2B, the wirings M4 having damascene structures are formed in an interlayer dielectric film IL4 in an upper portion of the semiconductor device 100. That is, the wirings M4 are formed by filling trenches formed in the interlayer dielectric film IL4 with conductive films mainly formed of copper.

An interlayer dielectric film IL5 is formed on the wirings M4. Via-plugs V4 are formed in the interlayer dielectric film IL5. The interlayer dielectric film IL5 is, for example, a silicon oxide film or a fluorine-doped silicon oxide film, and the via-plugs V4 are, for example, conductive films mainly formed of tungsten.

The wirings M5 are formed on the interlayer dielectric film IL5. The wirings M5 are electrically connected to the wirings M4 via the via-plugs V4. The wirings M5 are mainly formed of conductive films AL. Here, the case where the wirings M5 are formed of barrier metal films BM1, the conductive films AL formed on the barrier metal films BM1, and barrier metal films BM2 formed on the conductive films AL is exemplified.

The conductive films AL are aluminum films or an aluminum alloy films in which additives such as copper are added to the aluminum films. Each of the barrier metal films BM1 and the barrier metal films BM2 is a conductive film, and is, for example, a laminated film of a titanium nitride film and a titanium film. In the wirings M5, the barrier metal films BM2 may not be formed.

The protective film PVF is formed on the interlayer dielectric film IL5 so as to cover upper surfaces and side surfaces of the wirings M5. The protective film PVF is formed of inorganic dielectric films. In the first embodiment, the protective film PVF includes inorganic dielectric films IF1 to IF3.

As shown in 2A, the inorganic dielectric film IF1 is formed on each of the upper surfaces of the wirings M5. The inorganic dielectric film IF2 is formed on the upper surfaces of the wirings M5 via the inorganic dielectric film IF1 and is formed on the side surfaces of the wirings M5. The inorganic dielectric film IF3 is formed on the side surfaces of the wirings M5 via the inorganic dielectric film IF1 and the inorganic dielectric film IF2 and is formed on the upper surfaces of the wirings M5 via the inorganic dielectric film IF2.

The inorganic dielectric film IF1 is, for example, a silicon oxide film or a silicon nitride film. The inorganic dielectric film IF2 is, for example, a silicon oxide film or a silicon oxynitride film. The inorganic dielectric film IF3 is, for example, a silicon nitride film. A thickness of the inorganic dielectric film IF1 is 300 nm or more and 500 nm or less. A thickness of the inorganic dielectric film IF2 is 100 nm or more and 400 nm or less. A thickness of the inorganic dielectric film IF3 is 400 nm or more and 1000 nm or less. The numerical value of the thickness of each of the inorganic dielectric films IF1 to IF3 is a numerical value of the thickness in the Z direction, and is a numerical value of the thickness measured on the upper surfaces of the wirings M5.

In addition, the inorganic dielectric films IF2, IF3 are formed by PECVD (Plasma-enhanced Chemical Vapor Deposition) method using a parallel plate electrode, and therefore, the inorganic dielectric films IF2, IF3 are likely to be deposited substantially uniformly along the base shape. Therefore, the thicknesses of the inorganic dielectric films IF2, IF3 on the side surfaces of the wirings M5 are the same as or slightly smaller than the thicknesses of the inorganic dielectric films IF2, IF3 on the upper surfaces of the wirings M5.

In the first embodiment, a structure (non-filled structure) in which a space between the wirings M5 is not completely filled with the protective film PVF is applied. That is, as shown in FIG. 2A, except for being integrated on the interlayer dielectric film IL5, the protective films PVF (inorganic dielectric films IF3) formed on the side surfaces of the wirings M5 is spaced apart from each other. In other words, the protective films PVF (inorganic dielectric films IF3) formed on the side surfaces of the wirings M5 are connected via the protective film PVF formed on the interlayer dielectric film IL5 between the wirings M5 next to each other.

The inorganic dielectric film IF3 formed of a silicon nitride film serves to prevent moisture from entering from the outside of the semiconductor device 100. In order to maintain such roles and form the non-filled structure, it is preferable that the inorganic dielectric film IF3 is formed to be relatively thick and the inorganic dielectric film IF2 is formed to be relatively thin. That is, the thickness of the inorganic dielectric film IF3 is preferably larger than the thickness of the inorganic dielectric film IF2.

As shown in FIG. 2B, the opening portions OP1 are provided in the protective film PVF (inorganic dielectric films IF1 to IF3) on the upper surfaces of the wirings M5. Parts of the wirings M5 exposed in the opening portions OP1 serve as pad electrodes. When the barrier metal films BM2 are provided in the wirings M5, the barrier metal films BM2 are also removed in the opening portions OP1, and the conductive films AL are exposed.

In the opening portions OP1, external connection members WB are connected to the upper surfaces of the wirings M5. The external connection members WB are, for example, wires formed of gold or copper. Although not shown here, when the semiconductor device 100 is packaged, the wirings M5, the protective film PVF, and the external connection members WB are covered with a sealing resin such as an epoxy resin. In this case, a space between the wirings M5 next to each other is filled with the sealing resin.

### Problems of Examined Example

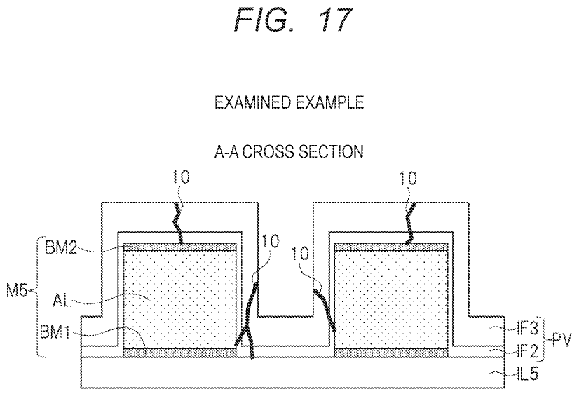

FIG. 17 shows the semiconductor device of the examined example studied by the inventor of the present application. In the protective film PVF of the examined example, the inorganic dielectric film IF1 of the first embodiment is not provided, and the protective film PVF is formed of the inorganic dielectric film IF2 and the inorganic dielectric film IF3. Therefore, a thickness of the protective film PVF on the side surfaces of the wirings M5 is approximately the same as the thickness of the protective film PVF on the upper surfaces of the wirings M5.

According to studies conducted by the inventor of the present application, it was found out that, for example, when the distance between the wirings M5 becomes a narrow space such as 2.7 μm or less, a crack (side surface crack) easily occur in the protective film PVF on the side surfaces of the wirings M5 during the manufacturing step of the semiconductor device 100 or in the wafer acceleration test.

The thermal expansion coefficient of the wirings M5 greater than the thermal expansion coefficient of the protective film PVF causes the side surface crack. For example, the thermal expansion coefficient of the aluminum film is 23 ppm/° C. The thermal expansion coefficient of the silicon oxide film is 0.55 ppm/° C. The thermal expansion coefficient of the silicon nitride film is 2.8 ppm/° C. The thermal expansion coefficient of the silicon oxynitride film is between the thermal expansion coefficient of the silicon oxide film and the thermal expansion coefficient of the silicon nitride film.

Here, the inventor of the present application have confirmed that the side surface crack can be prevented by reducing the thickness of the protective film PVF through experimentation. On the other hand, it has been found out that reduction of the thickness of the protective film PVF tends to generate a crack (upper surface crack) in the protective film PVF on the upper surfaces of the wirings M5 in the wafer acceleration test, the acceleration test after packaging, and the like.

That is, it was found out that the upper surface crack and the side surface crack are in a trade-off relationship with each other. However, since the thickness of the protective film PVF is substantially the same between on the upper surfaces of the wirings M5 and on the side surfaces of the wirings M5, it is difficult to suppress both upper surface crack and side surface crack.

### Main Features of First Embodiment

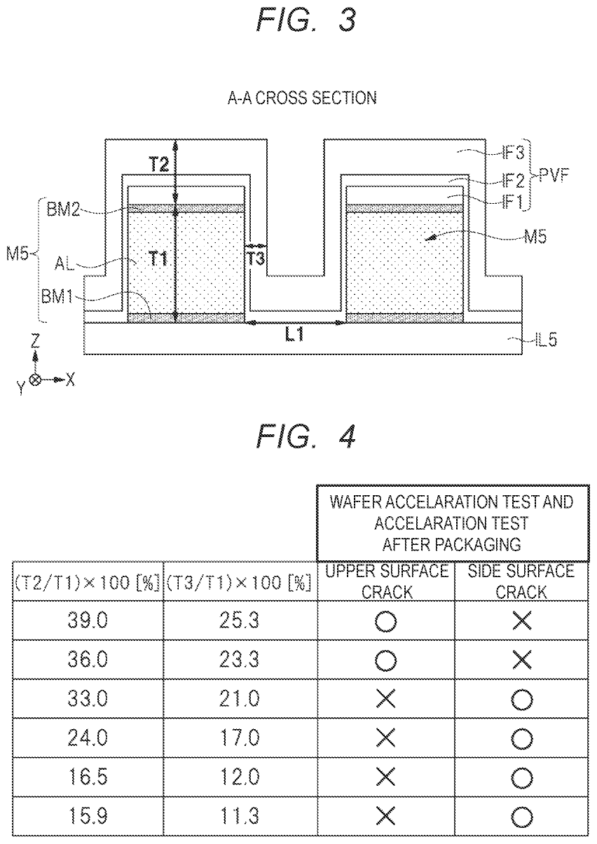

FIG. 3 shows the parameters used by the present inventor in the experiments. FIGS. 4 to 6 are data showing the results of experiments conducted by the present inventor.

The wirings M5 are next to each other spaced apart by a distance L1. Here, the distance between the lower surfaces of the two wirings M5 (the lower surfaces of the two barrier metal films BM1) is defined as the distance L1. A thickness T1 is the thickness of the wiring M5. A thickness T2 is the thickness of the protective film PVF formed on the upper surfaces of the wirings M5. In the first embodiment, the thickness T2 is the sum of the thicknesses of the inorganic dielectric films IF1 to IF3. A thickness T3 is the thickness of the protective film PVF formed on the side surfaces of the wirings M5. In the first embodiment, the thickness T3 is the sum of the thicknesses of the inorganic dielectric films IF2, IF3.

FIG. 4 shows obtained experimental results with setting the thickness T1 and the distance L1 to be within a range of 2.7 μm or more and 3.3 μm or less, and setting “thickness T1/distance L1” to be 1. Then, samples where the upper surface crack or the side surface crack is generated (x) and samples where the upper surface crack or the side surface crack is not generated (∘) are investigated when the thickness T2 and the thickness T3 are adjusted as appropriate.

As shown in FIG. 4, the result that the upper surface crack was not generated when the thickness T2 was made relatively thick and “(T2/T1)×100” was 36% or more, is obtained. On the other hand, the result that the side surface crack was not generated when the thickness T3 was made relatively thin and “(T3/T1)×100” was 21% or less, is obtained.

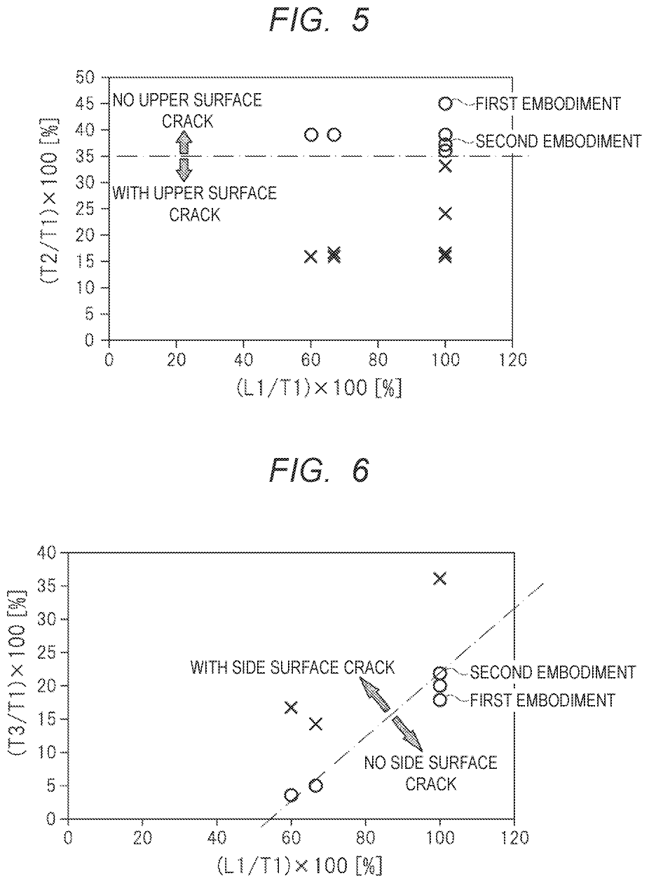

FIG. 5 shows the relationship between the thickness T2 and the distance L1 for the upper surface crack. As shown in FIG. 5, when “(T2/T1)×100” is 35% or more, generation of upper surface crack can be suppressed regardless of the value of “(L1/T1)×100”. Therefore, there is no dependence of the distance L1 on the thickness T2.

That is, for the upper surface crack, it is necessary to satisfy the following Equation 1 using a variable X is needed.

X=(T2/T1)×100≥35% Equation 1:

FIG. 6 is a graph showing the relationship between the thickness T3 and the distance L1 for the side surface crack. As shown in FIG. 5, the value of “(T3/T1)×100” for suppressing the generation of side surface crack varies depending on the value of “(L1/T1)×100”. Therefore, there is a dependency of the distance L1 on the thickness T3.

That is, for the side surface crack, it is necessary to satisfy the following Equations 2, 3, and 4 using a variable Y and a variable Z.

Y=(L1/T1)×100[%] Equation 2:

Z=(T3/T1)×100[%] Equation 3:

Z=0.476Y−25.8%(54.2%<Y<130%) Equation 4:

In the first embodiment, the distance L1 is set within a range of 1.8 μm or more and 3.3 μm or less, and the thickness T1 of the wirings M5 is set within a range of 2.7 μm or more and 3.3 μm or less. When the wirings M5 include the barrier metal films BM1, the conductive films AL, and the barrier metal films BM2, the sum of the thicknesses of the barrier metal films BM1, the conductive films AL, and the barrier metal films BM2 is set within a range of 2.7 μm or more and 3.3 μm or less. The thickness of each of the barrier metal films BM1 and the barrier metal films BM2 is 0.03 μm or more and 0.2 μm or less, and the other thickness is the thickness of the conductive films AL.

As described above, in the examined example, the protective film PVF is formed of the inorganic dielectric film IF2 and the inorganic dielectric film IF3. Therefore, since the thickness of the protective film PVF becomes substantially the same (T3) between on the upper surfaces of the wirings M5 and on the side surfaces of the wirings M5, it is difficult to suppress both upper surface crack and side surface crack.

In the first embodiment, the thickness of the protective film PVF on the upper surfaces of the wirings M5 is set to be larger than the thickness of the protective film PVF on the side surfaces of the wirings M5. That is, in order to suppress the side surface crack, by reducing the thickness of each of the inorganic dielectric film IF2 and the inorganic dielectric film IF3, the thickness of the protective film PVF on the side surfaces of the wirings M5 can be adjusted to an appropriate thickness. However, in such case, the thickness of each of the inorganic dielectric film IF2 and the inorganic dielectric film IF3 on the upper surfaces of the wirings M5 is also reduced.

Therefore, in the first embodiment different from the examined example, the inorganic dielectric film IF1 is formed on the upper surfaces of the wirings M5. Therefore, by increasing the thickness of the inorganic dielectric film IF1, the thickness of the protective film PVF on the upper surfaces of the wirings M5 can be adjusted to an appropriate thickness. As described above, in the first embodiment, since both upper surface crack and side surface crack can be suppressed, the reliability of the semiconductor device 100 can be improved.

### Manufacturing Method of Semiconductor Device

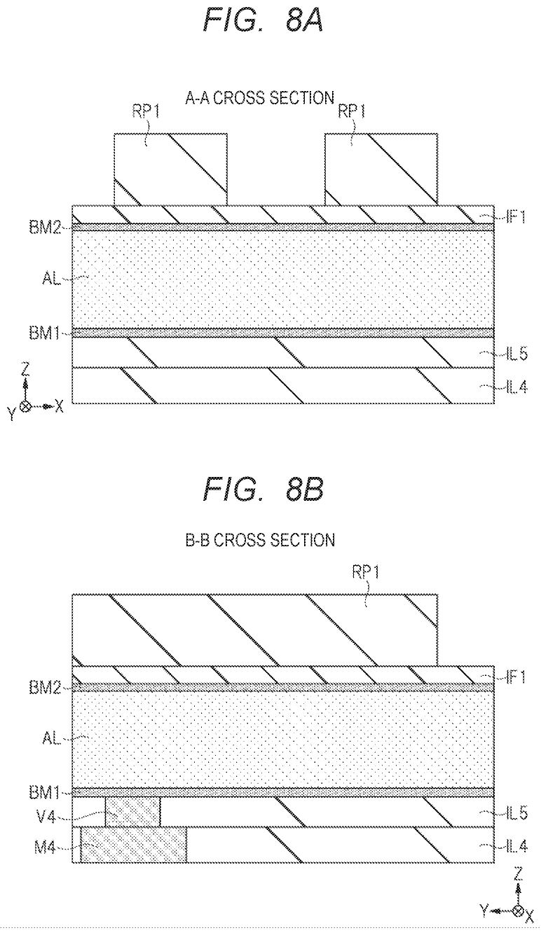

Hereinafter, the manufacturing method of the semiconductor device 100 in the first embodiment will be described with reference to FIGS. 7, 8A to 11A, and 8B to 11B. FIG. 7 is a cross-sectional view showing the wirings M4 and the lower layer structure thereof. FIGS. 8A to 11A are cross-sectional view corresponding to FIG. 2A. FIGS. 8B to 11B are cross-sectional view corresponding to FIG. 2B.

First, a part of the multilayer wiring layer and a part of manufacturing method thereof will be described with reference to FIG. 7. In FIG. 7, the manufacturing step of the wiring layers (wirings M1 to wirings M4) will be described, and the manufacturing step of the wirings M5 will be described in FIGS. 8A and 8B and thereafter. Note that the wiring layers (wirings M1 to wirings M4) and the wirings M5 configure the multilayer wiring layer in which the wirings M5 are the uppermost layer wirings.

As shown in FIG. 7, a semiconductor substrate SUB formed of p-type monocrystalline silicon or the like is prepared. At this stage, the semiconductor substrate SUB is in the wafer state. Next, element isolation regions STI defining active regions are formed in the semiconductor substrate SUB. The element isolation regions STI can be formed by forming trenches in the semiconductor substrate SUB and filling the trenches with a dielectric film such as a silicon oxide film.

Next, impurities are implanted into the semiconductor substrate SUB to form a well region WL. Next, semiconductor elements are formed on the semiconductor substrate. For example, a MISFET 1Q and a MISFET 2Q including a gate electrode formed on the well region WL via a gate dielectric film and source/drain regions formed in the well region WL are respectively formed.

Next, an interlayer dielectric film IL0 is formed on the semiconductor substrate SUB by, for example, a CVD method so as to cover the MISFET 1Q and the MISFET 2Q. The interlayer dielectric film IL0 is, for example, a silicon oxide film. Next, contact holes are formed in the interlayer dielectric film IL0 by a photolithography technique and a dry etching method. Next, a metal film such as tungsten is filled in the contact holes to form plugs PG. The plugs PG are connected to the MISFET 1Q, the MISFET 2Q, or the like.

Next, an interlayer dielectric film IL1 is formed on the interlayer dielectric film IL0 by, for example, a CVD method. The interlayer dielectric film IL1 is formed of a material having a lower dielectric constant than silicon oxide, and is, for example, a carbon-doped silicon oxide film such as SiOC. The wirings M1 is formed using a so-called damascene technique. That is, the wirings M1 is formed by forming trenches in the interlayer dielectric film IL1, filling the trenches with a conductive film mainly formed of copper, and then removing the conductive film formed outside the trenches by a CMP (Chemical Mechanical Polishing) method. Note that a barrier metal film that prevents copper from diffusing may be formed between copper and the interlayer dielectric film IL1. The wirings M1 is connected to upper surfaces of the plugs PG.

Next, an interlayer dielectric film IL2 is formed on the interlayer dielectric film IL1 by, for example, a CVD method so as to cover the wirings M1. The interlayer dielectric film IL2 is formed of the same material as the interlayer dielectric film IL1. Next, via-plugs V1 and wirings M2 are formed by forming via-holes and trenches for wirings in the interlayer dielectric film IL2, filling the via-holes and the trenches for wirings with a conductive film mainly formed of copper, and then removing the conductive film formed outside the via-holes and the trenches for wirings by a CMP method. That is, the via-plugs V1 and the wirings M2 are formed by a dual damascene (Dual Damascene) method, which is a kind of damascene method, and are integrated. Note that a barrier metal film that prevents copper from diffusing may be formed between copper and the interlayer dielectric film IL2. The via-plugs V1 are connected to upper surfaces of the wirings M1.

Next, an interlayer dielectric film IL3 is formed on the interlayer dielectric film IL2 by, for example, a CVD method so as to cover the wirings M2. Next, via-plugs V2 and wirings M3 are formed in the interlayer dielectric film IL3 by the same method as in the case where the via-plugs V1 and the wirings M2 are formed. Next, the interlayer dielectric film IL4 is formed on the interlayer dielectric film IL3 by, for example, a CVD method so as to cover the wirings M3. Next, via-plugs V3 and the wirings M4 are formed in the interlayer dielectric film IL4 by the same method as in the case where the via-plugs V1 and the wirings M2 are formed. The materials of the interlayer dielectric film IL3 and the interlayer dielectric film IL4 are the same as the material of the interlayer dielectric film IL2.

Note that the wirings M1 to the wirings M4 are not limited to the damascene structured wirings. The wirings M1 to the wirings M4 may be formed by forming a conductive film by a CVD method or a sputtering method and patterning the conductive film. Such a conductive film is, for example, a laminated film of a barrier metal film formed of a titanium nitride film and a titanium film, and an aluminum film. The via-plugs V1 to V3 are, for example, laminated films of a barrier metal film formed of a titanium nitride film and a titanium film, and a tungsten film.

Next, as shown in FIGS. 8A and 8B, the interlayer dielectric film IL5 is formed on the interlayer dielectric film IL4 by, for example, a CVD method so as to cover the wirings M4. The interlayer dielectric film IL5 is, for example, a silicon oxide film or a fluorine-doped silicon oxide film. Next, via-holes are formed in the interlayer dielectric film IL5 by a photolithography technique and a dry etching method. Next, the via-plugs V4 are formed by filling the via-holes with a conductive film mainly formed of tungsten. The via-plugs V4 are connected to upper surfaces of the wirings M4.

Next, the wirings M5 are formed on the interlayer dielectric film IL5. First, a conductive film for the wirings M5 is formed on the interlayer dielectric film IL5 by a CVD method or a sputtering method. Here, as an example of such a conductive film, the barrier metal film BM1, the conductive film AL, and the barrier metal film BM2 are sequentially laminated on the interlayer dielectric film IL5 by a CVD method or a sputtering method.

Next, the inorganic dielectric film IF1 is formed on the conductive film for the wirings M5 (on the barrier metal films BM2) by a CVD method. Here, PECVD method using the parallel plate electrode is applied. Next, a resist pattern RP1 is formed on the inorganic dielectric film IF1.

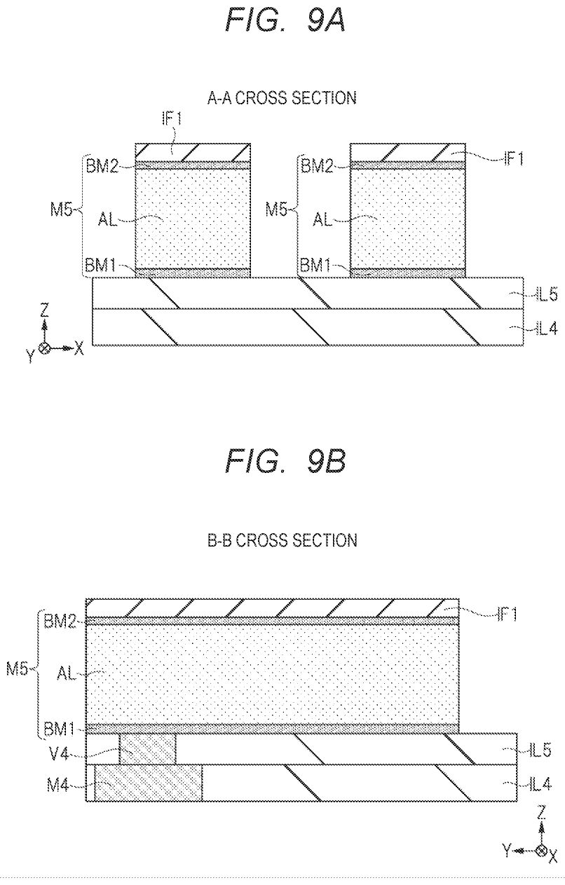

Next, as shown in FIGS. 9A and 9B, dry etching is performed on the inorganic dielectric film IF1, the barrier metal film BM2, the conductive film AL, and the barrier metal film BM1 using the resist pattern RP1 as a mask. As described above, the wirings M5 are formed by patterning the inorganic dielectric film IF1 and the conductive film for the wirings M5 (the barrier metal film BM2, the conductive film AL, and the barrier metal film BM1). The inorganic dielectric film IF1 is left on the upper surfaces of the wirings M5. The wirings M5 are next to each other spaced apart by the distance L1, as described in FIG. 3. Each of the wirings M5 is connected to an upper surface of the via-plug V4. Thereafter, the resist pattern RP1 is removed by an ashing process.

When the barrier metal films BM2 is not formed, a silicon oxynitride film may be formed on the conductive film AL prior to forming the inorganic dielectric film IF1. Such a silicon oxynitride film can function as an antireflection film at the time of forming the resist pattern RP1. Since the silicon oxynitride film is an inorganic dielectric film, the silicon oxynitride film may be left as a part of the protective film PVF.

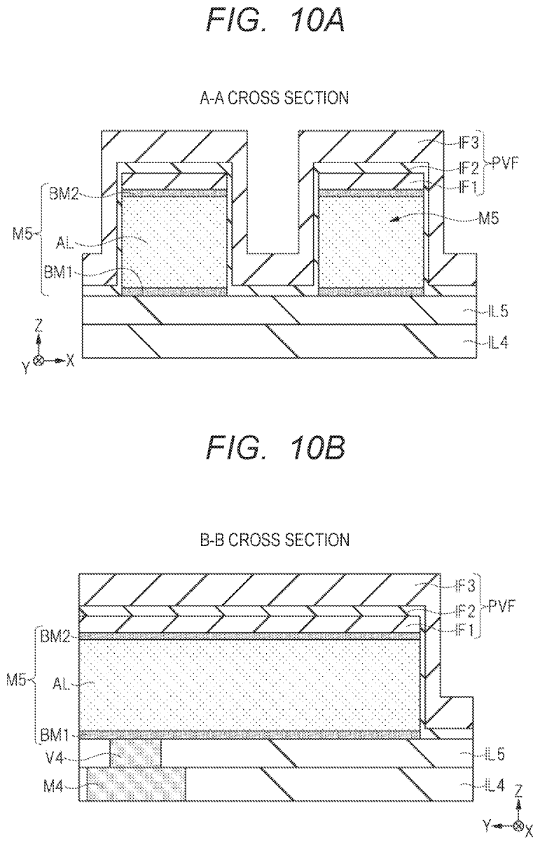

Next, as shown in FIGS. 10A and 10B, the inorganic dielectric film IF2 and the inorganic dielectric film IF3 are sequentially formed on the interlayer dielectric film IL5 by a CVD method so as to cover the wirings M5 and the inorganic dielectric film IF1. Here, PECVD method using the parallel plate electrode is applied. That is, first, the inorganic dielectric film IF2 is formed on the upper surfaces of the wirings M5 via the inorganic dielectric film IF1, and the inorganic dielectric film IF2 is formed on the side surfaces of the wirings M5. Then, the inorganic dielectric film IF3 is formed on the upper surfaces of the wirings M5 via the inorganic dielectric film IF1 and the inorganic dielectric film IF2, and the inorganic dielectric film IF3 is formed on the side surfaces of the wirings M5 via the inorganic dielectric film IF2.

In this manner, the protective film PVF having the inorganic dielectric films IF1 to IF3 and covering the wirings M5 is formed. Here, except for a portion integrated on the interlayer dielectric film IL5, the protective films PVF (inorganic dielectric films IF3) formed on the side surfaces of the wirings M5 are spaced apart from each other so as to realize the non-filled structure. That is, a space between the wirings M5 is not completely filled with the inorganic dielectric film IF2 and the inorganic dielectric film IF3.

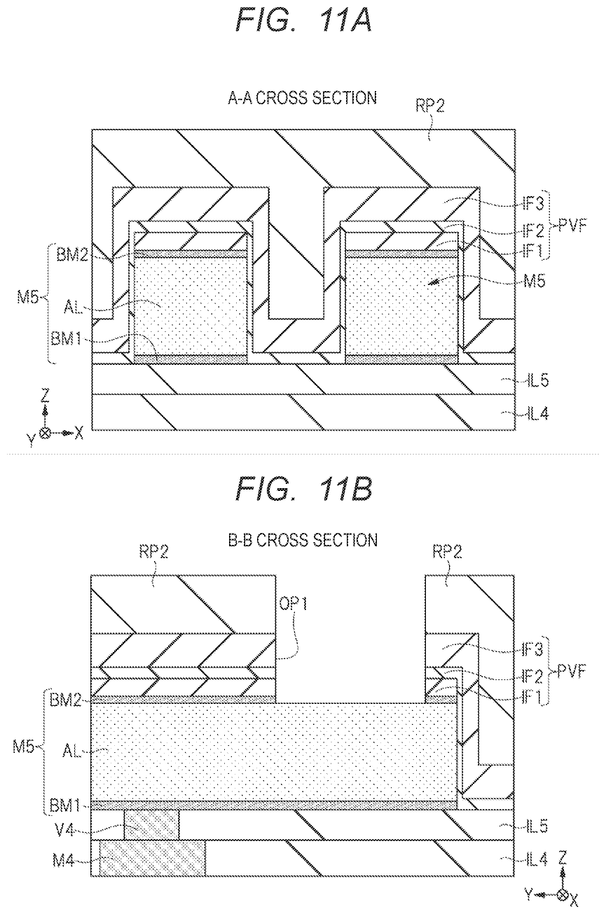

Next, as shown in FIGS. 11A and 11B, a resist pattern RP2 is formed on the protective film PVF (on the inorganic dielectric film IF3). Next, dry etching is performed on the inorganic dielectric film IF3, the inorganic dielectric film IF2, and the inorganic dielectric film IF1 using the resist pattern RP2 as a mask. As a result, the opening portions OP1 are formed in the protective film PVF (inorganic dielectric films IF1 to IF3) so as to reach parts of the upper surfaces of the wirings M5. The wirings M5 located in the opening portions OP1 serve as pad electrodes for connecting the external connection members WB. Thereafter, the resist pattern RP2 is removed by an ashing process.

When the barrier metal films BM2 are provided on the wirings M5, the barrier metal films BM2 in the opening portions OP1 are also removed by the dry etching process, and the conductive films AL are exposed.

Thereafter, the semiconductor device 100 shown in FIGS. 2A and 2B is manufactured through the following manufacturing steps. First, the semiconductor substrate SUB is singulated into semiconductor chips by performing a dicing step or the like on the wafer-state semiconductor substrate SUB. Next, the external connection members WB are connected to the upper surfaces of the wirings M5 in the opening portions OP1. The external connection members WB are, for example, wire bondings formed of gold or copper. Next, although not shown, the wirings M5, the protective film PVF, and the external connection members WB may be covered with a sealing resin such as an epoxy resin.

Note that, prior to performing the dicing step, redistribution wirings connected to the upper surfaces of the wirings M5 in the opening portions OP1 may be formed, and the external connection members WB may be connected on the redistribution wirings. First, a polyimide film is formed on the protective film PVF. Opening portions are formed in the polyimide film so as to reach the upper surfaces of the wirings M5 in the opening portions OP1. Then, the redistribution wirings are formed on the polyimide film by a plating method so as to be connected to the upper surfaces of the wirings M5 in the opening portions. The redistribution wirings are formed of, for example, conductive films mainly formed of copper. Thereafter, the dicing step is performed on the semiconductor substrate SUB, and the external connection members WB are connected to the redistribution wirings.

### Second Embodiment

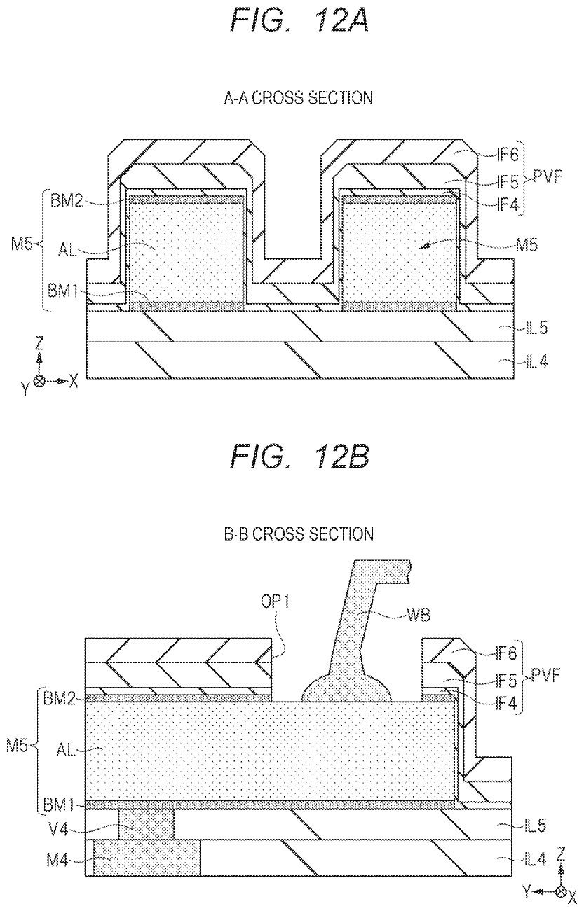

The semiconductor device in the second embodiment will be described below with reference to FIGS. 12A and 12B. Note that, in the following description, differences from the first embodiment will be mainly described, and the description of overlapping points with the first embodiment will be omitted.

In the first embodiment, the thickness of the protective film PVF on the upper surfaces of the wirings M5 is adjusted to an appropriate thickness mainly by increasing the thickness of the inorganic dielectric film IF1. In the second embodiment, the thickness of the protective film PVF on the upper surfaces of the wirings M5 is adjusted to an appropriate thickness mainly by the inorganic dielectric film IF5 formed by an HDP-CVD (High Density Plasma-CVD) method. Thus, even in the second embodiment, the thickness of the wirings M5 on the upper surfaces of the wirings M5 is set to be larger than the thickness of the protective film PVF on the side surfaces of the wirings M5.

As shown in FIG. 12A, the protective film PVF is formed of inorganic dielectric films and has inorganic dielectric films IF4 to IF6. The inorganic dielectric film IF4 is formed on the upper surfaces of the wirings M5 and on the side surfaces of the wirings M5. The inorganic dielectric film IF5 is formed on the upper surfaces of the wirings M5 via the inorganic dielectric film IF4, and formed on the side surfaces of the wirings M5 via the inorganic dielectric film IF4. The inorganic dielectric film IF5 is formed on the upper surfaces of the wirings via the inorganic dielectric film IF4 and the inorganic dielectric film IF5, and formed on the side surfaces of the wirings M5 via the inorganic dielectric film IF4 and the inorganic dielectric film IF5.

The inorganic dielectric film IF4 is, for example, a silicon oxide film. The inorganic dielectric film IF5 is, for example, a silicon oxide film. The inorganic dielectric film IF6 is, for example, a silicon nitride film. A thickness of the inorganic dielectric film IF4 is 50 nm or more and 130 nm or less. A thickness of the inorganic dielectric film IF5 is 100 nm or more and 200 nm or less. A thickness of the inorganic dielectric film IF6 is 600 nm or more and 1100 nm or less. The numerical value of the thickness of each of the inorganic dielectric films IF4 to IF6 is a numerical value of the thickness in the Z direction, and is a numerical value of the thickness measured on the upper surfaces of the wirings M5.

Further, since the inorganic dielectric films IF4, IF6 are formed by a PECVD method using a parallel plate electrode, the thicknesses of the inorganic dielectric films IF4, IF6 on the side surfaces of the wirings M5 are the same as or slightly thinner than the thicknesses of the inorganic dielectric films IF4, IF6 on the upper surfaces of the wirings M5.

In addition, the inorganic dielectric film IF6 formed of a silicon nitride film serves to prevent moisture from entering from the outside of the semiconductor device 100, similarly to the inorganic dielectric film IF3 of the first embodiment. In order to maintain such roles and form the non-filled structure, it is preferable to form the inorganic dielectric film IF6 to be relatively thick, and to form the inorganic dielectric film IF4 and the inorganic dielectric film IF5 to be relatively thin. That is, it is preferable that the thickness of the inorganic dielectric film IF6 is larger than the thickness of each of the inorganic dielectric film IF4 and the inorganic dielectric film IF5.

The inorganic dielectric film IF5 is formed using the HDP-CVD method. The HDP-CVD method is a film forming method in which deposition of the film by plasma treatment and the etching by sputtering are repeated. By etching by sputtering, the corner portions of the inorganic dielectric film IF5 are easily scraped. Consequently, above the corner portions of the wirings M5, the inorganic dielectric film IF5 is inclined with respect to the upper surfaces and the side surfaces of the wirings M5. The thickness of the inorganic dielectric film IF5 is reduced on the side surfaces of the wirings M5. The thickness of the inorganic dielectric film IF5 on the upper surfaces of the wirings M5 is sufficiently larger than and more than twice the thickness of the inorganic dielectric film IF5 on the side surfaces of the wirings M5. The thickness of the inorganic dielectric film IF5 on the upper surfaces of the wirings M5 is 100 nm or more and 200 nm or less, and the thickness of the inorganic dielectric film IF5 on the side surfaces of the wirings M5 is 24 nm or more and 48 nm or less.

In addition, since the inclined portion is formed on the inorganic dielectric film IF5, the inorganic dielectric film IF6 can be formed with a reduced aspect-ratio. As described above, since the inorganic dielectric film IF6 is preferable formed to be thick, the inorganic dielectric film IF6 is more likely to be formed to be thicker and have a uniform thickness when the aspect-ratio is reduced.

As shown in FIG. 12B, the opening portions OP1 are provided in the protective film PVF (inorganic dielectric films IF4 to IF6) on the upper surfaces of the wirings M5. Parts of the wirings M5 exposed in the opening portions OP1 serve as pad electrodes. The external connection members WB are connected to the upper surfaces of the wirings M5 in the opening portions OP1.

Similar to the first embodiment, when the semiconductor device 100 is packaged, the wirings M5, the protective film PVF, and the external connection members WB are covered with a sealing resin such as an epoxy resin. In this case, a space between the wirings M5 next to each other is filled with the sealing resin.

The protective film PVF in the second embodiment also covers the upper surfaces and the side surfaces of the wirings M5 and the non-filled structure is realized. Also, in the second embodiment, the relationship of Equations 1 to 4 described above are satisfied. Therefore, even in the second embodiment, since both upper surface crack and side surface crack can be suppressed, the reliability of the semiconductor device 100 can be improved.

Note that the distance L1 and the thickness T1 in the second embodiment are the same as those in the first embodiment. In the second embodiment, the thickness T2 of the protective film PVF formed on the upper surfaces of the wirings M5 is the sum of the thicknesses of the inorganic dielectric films IF4 to IF6. In the second embodiment, the thickness T3 of the protective film PVF formed on the side surfaces of the wirings M5 is the sum of the thicknesses of the inorganic dielectric films IF4 to IF6.

### Manufacturing Method of Semiconductor Device in Second Embodiment

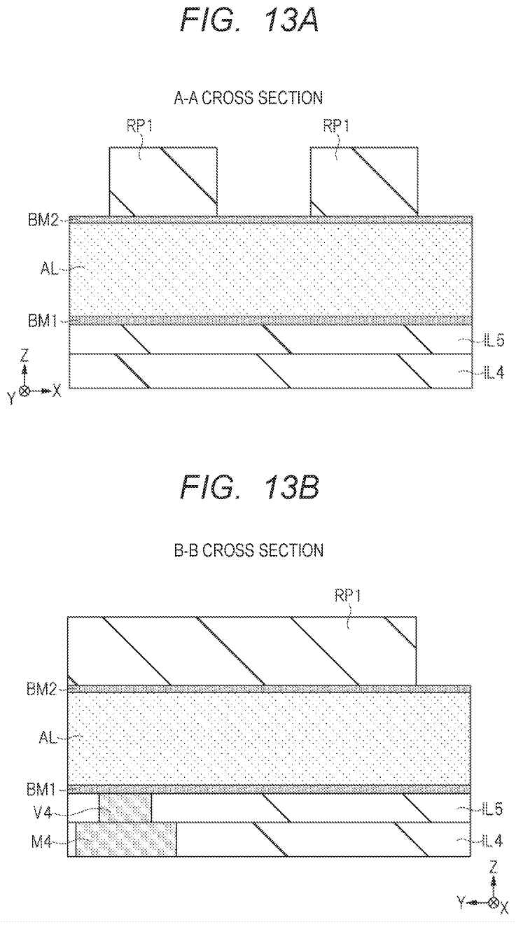

The manufacturing method of the semiconductor device 100 in the second embodiment will be described below with reference to FIGS. 13A to 16A and 13B to 16B. The manufacturing steps in the second embodiment are the same as the manufacturing steps in the first embodiment until a conductive film for the wirings M5 is formed on the interlayer dielectric film IL5.

As shown in FIGS. 13A and 13B, as an exemplary conductive film for the wirings M5, the barrier metal film BM1, the conductive film AL, and the barrier metal film BM2 are sequentially laminated on the interlayer dielectric film IL5 by a CVD method or a sputtering method. Next, the resist pattern RP1 is formed on the conductive film for the wirings M5 (on the barrier metal film BM2).

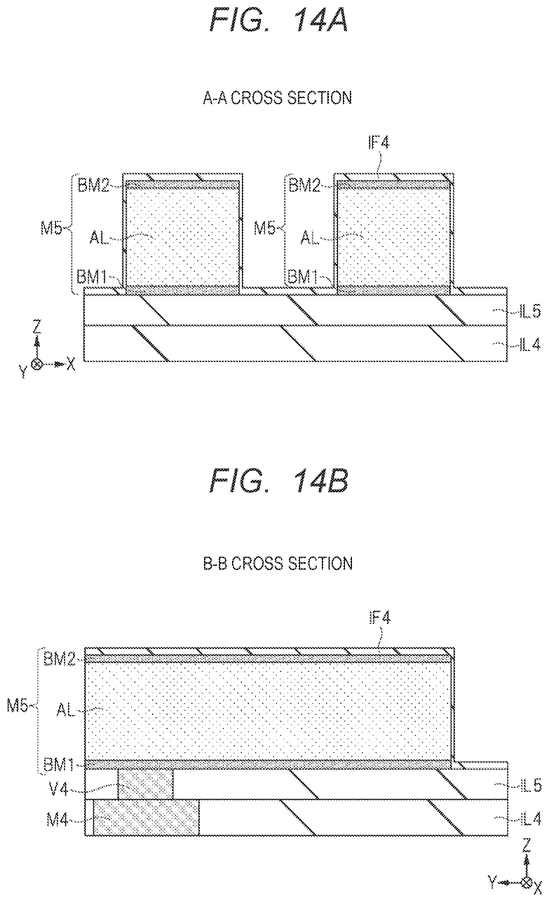

Next, as shown in FIGS. 14A and 14B, dry etching is performed on the barrier metal film BM2, the conductive film AL, and the barrier metal film BM1 using the resist pattern RP1 as a mask. As described above, by patterning the conductive film for the wirings M5 (the barrier metal film BM2, the conductive film AL, and the barrier metal film BM1), the multilayer wiring layer having the wirings M5 as the uppermost layer wirings is formed on the semiconductor substrate SUB. Note that the wirings M5 are next to each other spaced apart by the distance L1. Each of the wirings M5 is connected to the upper surface of the via-plug V4. Thereafter, the resist pattern RP1 is removed by an ashing process.

When the barrier metal film BM2 is not formed, a silicon oxynitride film may be formed on the conductive film AL. Such a silicon oxynitride film can function as an antireflection film at the time of forming the resist pattern RP1. Since the silicon oxynitride film is an inorganic dielectric film, the silicon oxynitride film may be left as a part of the protective film PVF.

Next, by the CVD method, the inorganic dielectric film IF4 is formed on the upper surfaces of the wirings M5 and formed on the side surfaces of the wirings M5. Here, a PECVD method using the parallel plate electrode is applied.

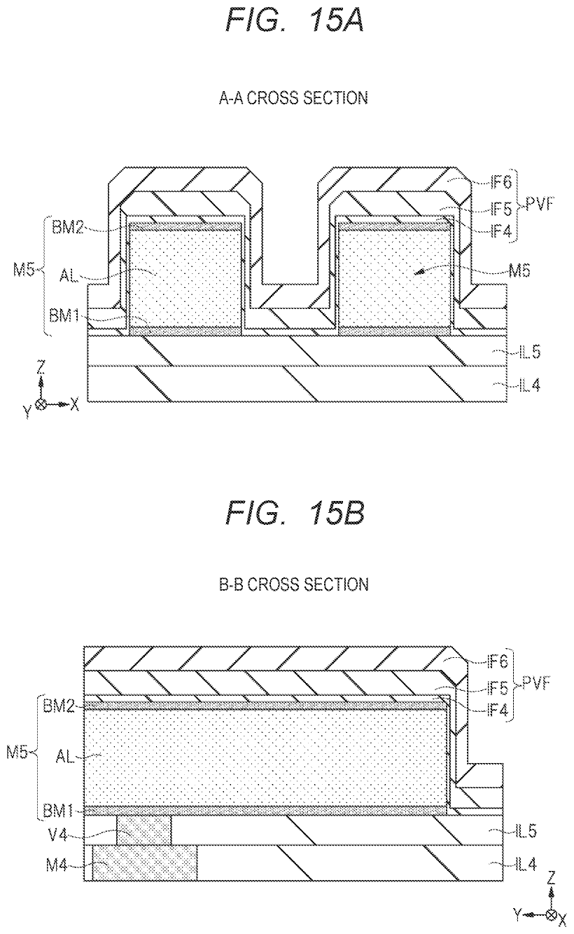

Next, as shown in FIGS. 15A and 15B, by the CVD method, the inorganic dielectric film IF5 is formed on the upper surfaces of the wirings M5 via the inorganic dielectric film IF4, and formed on the side surfaces of the wirings M5 via the inorganic dielectric film IF4. Here, the HDP-CVD method is applied. Therefore, above the corner portions of the wirings M5, the inorganic dielectric film IF5 is inclined with respect to the upper surfaces and the side surfaces of the wirings M5.

Next, by the CVD method, the inorganic dielectric film IF6 is formed on the upper surfaces of the wirings M5 via the inorganic dielectric film IF4 and the inorganic dielectric film IF5, and formed on the side surfaces of the wirings M5 via the inorganic dielectric film IF4 and the inorganic dielectric film IF5. Here, the PECVD method using the parallel plate electrode is applied. The inorganic dielectric film IF6 is deposited substantially uniformly along the shape of the underlying inorganic dielectric film IF5.

In this manner, the protective film PVF having the inorganic dielectric films IF4 to IF6 and covering the wirings M5 is formed. In the second embodiment, except for a portion integrated on the interlayer dielectric film IL5, the protective film PVF (inorganic dielectric film IF6) formed on the side surface of one of the wirings M5 is spaced apart from the protective film PVF (inorganic dielectric film IF6) formed on the side surface of another one of the wirings M5 so as to realize the non-filled structure. That is, a space between the wirings M5 is not completely filled with the inorganic dielectric films IF4 to IF6.

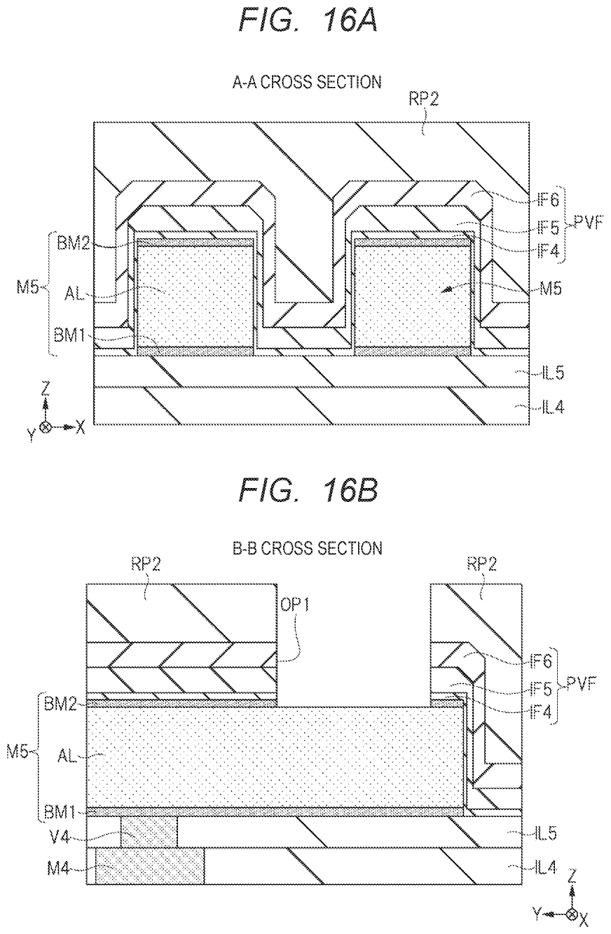

Next, as shown in FIGS. 16A and 16B, the resist pattern RP2 is formed on the protective film PVF (on the inorganic dielectric film IF6). Next, dry etching is performed on the inorganic dielectric film IF6, the inorganic dielectric film IF5, and the inorganic dielectric film IF4 using the resist pattern RP2 as a mask. As a result, the opening portions OP1 are formed in the protective film PVF (inorganic dielectric films IF4 to IF6) so as to reach parts of the upper surfaces of the wirings M5. The wirings M5 located in the opening portions OP1 serve as pad electrodes for connecting the external connection members WB. Thereafter, the resist pattern RP2 is removed by an ashing process.

When the barrier metal films BM2 are provided on the wirings M5, the barrier metal films BM2 is also removed in the opening portions OP1 by the dry etching process, and the conductive films AL are exposed.

Thereafter, as in the first embodiment, the semiconductor device 100 shown in FIGS. 12A and 12B is manufactured through the manufacturing steps such as the dicing step, the external connection members WB forming step, and the sealing step using the sealing resin.

Although the present invention has been described in detail based on the above-described embodiments, the present invention is not limited to the above-described embodiments, and can be variously modified without departing from the gist thereof.

What is claimed is:

1. A semiconductor device comprising:
a multilayer wiring layer formed on a semiconductor substrate;
a first wiring and a second wiring formed in an uppermost layer of the multilayer wiring layer and being next to each other spaced apart by a first distance; and
a protective film formed so as to cover an upper surface and a side surface of each of the first wiring and the second wiring,
wherein the protective film formed on the side surface of the first wiring and the protective formed on the side surface of the second wiring are spaced apart from each other,
wherein the protective film is formed of an inorganic dielectric film, and
wherein a thickness of the protective film formed on the upper surface of the first wiring or on the upper surface of the second wiring is larger than a thickness of the protective film formed on the side surface of the first wiring or on the side surface of the second wiring.

2. The semiconductor device according to claim 1,
wherein, when the first distance is defined as L1, a thickness of the first wiring or the second wiring is defined as T1, the thickness of the protective film formed on the upper surface of the first wiring or on the upper surface of the second wiring is defined as T2, and the thickness of the protective film formed on the side surface of the first wiring or on the side surface of the second wiring is defined as T3, the semiconductor device satisfies following relationship using a variable X, a variable Y and a variable Z:
X=(T2/T1)×100≥35%
Y=(L1/T1)×100[%]
Z=(T3/T1)×100[%]
Z=0.476Y−25.8%(54.2%<Y<130%)

3. The semiconductor device according to claim 2,
wherein the thickness (T1) of the first wiring or the second wiring is 2.7 μm or more and 3.3 μm or less, and
wherein the first distance (L1) is 1.8 μm or more and 3.3 μm or less.

4. The semiconductor device according to claim 2, comprising:
a first opening portion provided in the protective film so as to reach a part of the upper surface of the first wiring;
a second opening portion provided in the protective film so as to reach a part of the upper surface of the second wiring;
a first external connection material connected to the upper surface of the first wiring in the first opening portion; and
a second external connection material connected to the upper surface of the second wiring in the second opening portion.

5. The semiconductor device according to claim 2,
wherein the protective film includes:
a first inorganic dielectric film formed on the upper surface of each of the first wiring and the second wiring;
a second inorganic dielectric film formed on the upper surface of each of the first wiring and the second wiring via the first inorganic dielectric film and formed on the side surface of each of the first wiring and the second wiring; and
a third inorganic dielectric film formed on the upper surface of each of the first wiring and the second wiring via the first inorganic dielectric film and the second inorganic dielectric film and formed on the side surface of each of the first wiring and the second wiring via the second inorganic dielectric film.

6. The semiconductor device according to claim 5,
wherein the first inorganic dielectric film is a silicon oxide film or a silicon nitride film,
wherein the second inorganic dielectric film is a silicon oxide film or a silicon oxynitride film, and
wherein the third inorganic dielectric film is a silicon nitride film.

7. The semiconductor device according to claim 2,
wherein the protective film includes:
a fourth inorganic dielectric film formed on the upper surface of each of the first wiring and the second wiring and formed on the side surface of each of the first wiring and the second wiring;
a fifth inorganic dielectric film formed on the upper surface of each of the first wiring and the second wiring via the fourth inorganic dielectric film and formed on the side surface of each of the first wiring and the second wiring via the fourth inorganic dielectric film; and
a sixth inorganic dielectric film formed on the upper surface of each of the first wiring and the second wiring via the fourth inorganic dielectric film and the fifth inorganic dielectric film and formed on the side surface of each of the first wiring and the second wiring via the fourth inorganic dielectric film and the fifth inorganic dielectric film, and
wherein a thickness of the fifth inorganic dielectric film formed on the upper surface of the first wiring or on the upper surface of the second wiring is more than twice a thickness of the fifth inorganic dielectric film formed on the side surface of the first wiring or on the side surface of the second wiring.

8. The semiconductor device according to claim 7,
wherein, above a corner portion of each of the first wiring and the second wiring, the fifth inorganic dielectric film is inclined with respect to the upper surface and the side surface of each of the first wiring and the second wiring,
wherein a thickness of the sixth inorganic dielectric film formed on the side surface of the first wiring or on the side surface of the second wiring is larger than a thickness of each of the fourth inorganic dielectric film and the fifth inorganic dielectric film formed on the side surface of the first wiring or on the side surface of the second wiring.

9. The semiconductor device according to claim 8,
wherein the fourth inorganic dielectric film is a silicon oxide film,
wherein the fifth inorganic dielectric film is a silicon oxide film, and
wherein the sixth inorganic dielectric film is a silicon nitride film.

10. A method of manufacturing a semiconductor device, the method comprising:
(a) forming wiring layers on a semiconductor substrate;
(b) forming a first conductive film on the wiring layers;
(c) forming a first inorganic film on the first conductive film;
(d) patterning the first inorganic dielectric film and the first conductive film to form a first wiring and a second wiring next to each other spaced apart by a first distance such that the first inorganic dielectric film is left on an upper surface of each of the first wiring and the second wiring;
(e) forming a second inorganic dielectric film on the upper surface of each of the first wiring and the second wiring via the first inorganic dielectric film, and forming the second inorganic dielectric film on a side surface of each of the first wiring and the second wiring; and
(f) forming a third inorganic dielectric film on the upper surface of each of the first wiring and the second wiring via the first inorganic dielectric film and the second inorganic dielectric film, and forming the third inorganic dielectric film on the side surface of each of the first wiring and the second wiring via the second inorganic dielectric film,
wherein the wiring layers, the first wiring and the second wiring configure a multilayer wiring layer where the first wiring and the second wiring are uppermost layer wirings,
wherein the third inorganic dielectric film formed on the side surface of the first wiring and the third inorganic dielectric film formed on the side surface of the second wiring are spaced apart from each other, and
wherein a sum of thicknesses of the first inorganic dielectric film, the second inorganic dielectric film and the third inorganic dielectric film formed on the upper surface of the first wiring or on the upper surface of the second wiring is larger than a sum of thicknesses of the second inorganic dielectric film and the third inorganic dielectric film formed on the side surface of the first wiring or on the side surface of the second wiring.

11. The method according to claim 10,
wherein, when the first distance is defined as L1, a thickness of the first wiring or the second wiring is defined as T1, the sum of the thicknesses of the first inorganic dielectric film, the second inorganic dielectric film and the third inorganic dielectric film formed on the upper surface of the first wiring or on the upper surface of the second wiring is defined as T2, and the sum of the thicknesses of the second inorganic dielectric film and the third inorganic dielectric film formed on the side surface of the first wiring or on the side surface of the second wiring is defined as T3, the semiconductor device satisfies following relationship using a variable X, a variable Y and a variable Z:
X=(T2/T1)×100≥35%
Y=(L1/T1)×100[%]
Z=(T3/T1)×100[%]
Z=0.476Y−25.8%(54.2%<Y<130%)

12. The method according to claim 11,
wherein the thickness (T1) of the first wiring or the second wiring is 2.7 μm or more and 3.3 μm or less, and
wherein the first distance (L1) is 1.8 μm or more and 3.3 μm or less.

13. The method according to claim 11, comprising:
(g) forming a first opening portion in the first inorganic dielectric film, the second inorganic dielectric film and the third inorganic dielectric film so as to reach a part of the upper surface of the first wiring, and forming a second opening portion in the first inorganic dielectric film, the second inorganic dielectric film and the third inorganic dielectric film so as to reach a part of the upper surface of the second wiring,
wherein the first wiring located in the first opening portion and the second wiring located in the second opening each serves as a pad electrode for connecting an external connection material.

14. The method according to claim 11,
wherein the first inorganic dielectric film is a silicon oxide film or a silicon nitride film,
wherein the second inorganic dielectric film is a silicon oxide film or a silicon oxynitride film, and
wherein the third inorganic dielectric film is a silicon nitride film.

15. A method of manufacturing a semiconductor device, the method comprising:
(a) forming a multilayer wiring layer including a first wiring and a second wiring next to each other spaced apart by a first distance on a semiconductor substrate, the first wiring and the second wiring being uppermost layer wirings;
(b) forming a fourth inorganic dielectric film on an upper surface of each of the first wiring and the second wiring, and forming the fourth inorganic dielectric film on a side surface of each of the first wiring and the second wiring;
(c) forming a fifth inorganic dielectric film on the upper surface of each of the first wiring and the second wiring via the fourth inorganic dielectric film, and forming the fifth inorganic dielectric film on the side surface of each of the first wiring and the second wiring via the fourth inorganic dielectric film; and
(d) forming a sixth inorganic dielectric film on the upper surface of each of the first wiring and the second wiring via the fourth inorganic dielectric film and the fifth inorganic dielectric film, and forming the sixth inorganic dielectric film on the side surface of each of the first wiring and the second wiring via the fourth inorganic dielectric film and the fifth inorganic dielectric film,
wherein a thickness of the fifth inorganic dielectric film formed on the upper surface of the first wiring or on the upper surface of the second wiring is more than twice a thickness of the fifth inorganic dielectric film formed on the side surface of the first wiring or on the side surface of the second wiring,
wherein the sixth inorganic dielectric film formed on the side surface of the first wiring and the sixth inorganic dielectric film formed on the side surface of the second wiring are spaced apart from each other, and
wherein a sum of thicknesses of the fourth inorganic dielectric film, the fifth inorganic dielectric film and the sixth inorganic dielectric film formed on the upper surface of the first wiring or on the upper surface of the second wiring is larger than a sum of thicknesses of the fourth inorganic dielectric film, the fifth inorganic dielectric film and the sixth inorganic dielectric film formed on the side surface of the first wiring or on the side surface of the second wiring.

16. The method according to claim 15,
wherein, when the first distance is defined as L1, a thickness of the first wiring or the second wiring is defined as T1, the sum of the thicknesses of the fourth inorganic dielectric film, the fifth inorganic dielectric film and the sixth inorganic dielectric film formed on the upper surface of the first wiring or on the upper surface of the second wiring is defined as T2, and the sum of the thicknesses of the fourth inorganic dielectric film, the fifth inorganic dielectric film and the sixth inorganic dielectric film formed on the side surface of the first wiring or on the side surface of the second wiring is defined as T3, the semiconductor device satisfies following relationship using a variable X, a variable Y and a variable Z:
X=(T2/T1)×100≥35%
Y=(L1/T1)×100[%]
Z=(T3/T1)×100[%]
Z=0.476Y−25.8%(54.2%<Y<130%)

17. The method according to claim 16,
wherein the thickness (T1) of the first wiring or the second wiring is 2.7 μm or more and 3.3 μm or less, and
wherein the first distance (L1) is 1.8 μm or more and 3.3 μm or less.

18. The method according to claim 16, comprising:
(e) forming a first opening portion in the fourth inorganic dielectric film, the fifth inorganic dielectric film and the sixth inorganic dielectric film so as to reach a part of the upper surface of the first wiring, and forming a second opening portion in the fourth inorganic dielectric film, the fifth inorganic dielectric film and the sixth inorganic dielectric film so as to reach a part of the upper surface of the second wiring,
wherein the first wiring located in the first opening portion and the second wiring located in the second opening each serves as a pad electrode for connecting an external connection material.

19. The method according to claim 16,
wherein the fifth inorganic dielectric film is formed by an HDP-CVD method,
wherein, above a corner portion of each of the first wiring and the second wiring, the fifth inorganic dielectric film is inclined with respect to the upper surface and the side surface of each of the first wiring and the second wiring, and
wherein the sixth inorganic dielectric film is formed along a shape of the fifth inorganic dielectric film.

20. The method according to claim 19,
wherein a thickness of the sixth inorganic dielectric film formed on the side surface of the first wiring or on the side surface of the second wiring is larger than a thickness of each of the fourth inorganic dielectric film and the fifth inorganic dielectric film formed on the side surface of the first wiring or on the side surface of the second wiring.
